(19) United States
(12) Patent Application Publication
(10) Pub. No.: US 2024/0199950 A1
(43) Pub. Date: Jun. 20, 2024

(54) QUANTUM DOT, METHOD OF PREPARING THE SAME, AND ELECTRONIC APPARATUS INCLUDING THE SAME

(71) Applicant: Samsung Display Co., LTD., Yongin-si (KR)

(72) Inventors: Junehyuk Jung, Yongin-si (KR); Sungjae Kim, Yongin-si (KR); Youngsik Kim, Yongin-si (KR); Seungwon Park, Yongin-si (KR); Bitna Yoon, Yongin-si (KR); Donghee Lee, Yongin-si (KR)

(21) Appl. No.: 18/537,079

(22) Filed: Dec. 12, 2023

(30) Foreign Application Priority Data
Dec. 15, 2022 (KR) 10-2022-0176254

(51) Int. Cl. C09K 11/62; C09K 11/58

(52) U.S. Cl. CPC C09K 11/623; C09K 11/584

(57) ABSTRACT

Provided are a quantum dot, a method of preparing the same, and an electronic apparatus including the same, the quantum dot including a core including copper (Cu), a Group III element, a Group VI element, and gallium (Ga), a first shell covering the core, and a second shell covering the first shell, wherein the first shell includes a Group III-VI compound.

### CROSS-REFERENCE TO RELATED APPLICATION

This application claims priority to and the benefit of Korean Patent Application No. 10-2022-0176254, filed on Dec. 15, 2022, in the Korean Intellectual Property Office, the entire content of which is incorporated by reference herein.

### BACKGROUND

### 1. Field

Embodiments of the present disclosure relate to a quantum dot, a method of preparing the quantum dot, and an electronic apparatus including the quantum dot.

### 2. Description of the Related Art

Quantum dots are nanocrystals of semiconductor materials and exhibit a quantum confinement effect. When reaching an energy-excited state by receiving light from an excitation source, quantum dots emit energy according to a corresponding energy band gap by themselves. In this regard, even in the case of the same material, the wavelength varies depending on the particle size, and accordingly, by adjusting the size of quantum dots, light having a suitable or desired wavelength range may be obtained, and excellent color purity and high luminescence efficiency may be obtained. Thus, quantum dots are applicable to various suitable devices or apparatuses.

### SUMMARY

According to one or more embodiments, provided are a quantum dot having excellent chemical stability and photoluminescence characteristics, and a method of preparing the quantum dot.

Additional aspects of embodiments will be set forth in part in the description which follows and, in part, will be apparent from the description, or may be learned by practice of the presented embodiments of the disclosure.

According to one or more embodiments, a quantum dot includes:
a core including copper (Cu), a Group III element, a Group VI element, and gallium (Ga),
a first shell covering the core, and
a second shell covering the first shell,
wherein the first shell includes a Group III-VI compound.

According to one or more embodiments, provided is a method of preparing the quantum dot.

According to one or more embodiments, an electronic apparatus includes the quantum dot.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic cross-sectional view of a structure of a quantum dot according to an embodiment; and

FIG. 2 is a diagram showing photoluminescence (PL) spectra of quantum dots at 25° C., each prepared according to Example 1 and Comparative Examples 1 to 3.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The subject matter of the present disclosure can apply various suitable transformations and have various suitable embodiments, and thus, specific embodiments are illustrated in the drawings and described in more detail in the detailed description. An effect and a characteristic of embodiments of the disclosure, and a method of accomplishing these will be apparent when referring to embodiments described with reference to the drawings. The subject matter of the disclosure may, however, be embodied in many different forms and should not be construed as limited to the embodiments set forth herein.

It will be understood that although the terms “first,” “second,” etc. used herein may be used herein to describe various components, these components should not be limited by these terms. These components are only used to distinguish one component from another.

An expression used in the singular encompasses the expression of the plural, unless it has a clearly different meaning in the context.

It will be further understood that the terms “includes” and/or “comprises” used herein specify the presence of stated features or elements, but do not preclude the presence or addition of one or more other features or elements. Unless defined otherwise, the terms “include or have” may refer to both the case of consisting of features or components described in a specification and the case of further including other components.

The term “Group II” as used herein may include a Group IIA element and a Group IIB element on the IUPAC periodic table, and examples of the Group II element are zinc (Zn), cadmium (Cd), mercury (Hg), and copernicium (Cn), but are not limited thereto.

The term “Group III” as used herein may include a Group IIIA element and a Group IIIB element on the IUPAC periodic table, and examples of the Group III element are aluminum (AI), indium (In), gallium (Ga), thallium (TI), and nihonium (Nh), but are not limited thereto.

The term “Group VI” as used herein may include a Group VIA element and a Group VIB element on the IUPAC periodic table, and examples of the Group VI element are oxygen (O), sulfur (S), selenium (Se), and tellurium (Te), but are not limited thereto.

The terms “quantum yield” and “luminescence efficiency” may be used substantially in the same meaning.

Hereinafter, a quantum dot according to an embodiment and a method of preparing the same will be described.

In an embodiment, the quantum dot may include: a core including copper (Cu), a Group III element, a Group VI element, and gallium (Ga);
a first shell covering the core; and
a second shell covering the first shell,
wherein the first shell includes a Group III-VI compound.

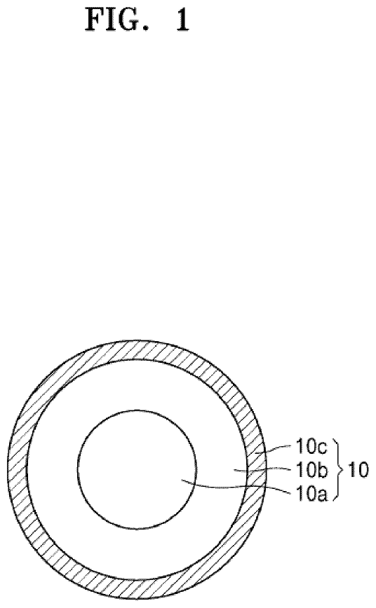

A cross-sectional view of a quantum dot 10 is shown in FIG. 1. The quantum dot 10 includes a core 10a, a first shell 10b, and a second shell 10c.

In an embodiment, an amount of Ga included in the core may be in a range of about 1 part by weight to about 200 parts by weight based on 100 parts by weight of the Group III element.

In an embodiment, the Group Ill element included in the core may be aluminum Al, In, and/or TI.

In an embodiment, the core may include Cu, In, Ga, and S.

In an embodiment, the core may include, based on 100 parts by weight of the core, Cu in a range of about 5 parts by weight to about 20 parts by weight, In in a range of about 10 parts by weight to about 30 parts by weight, Ga in a range of about 10 parts by weight to about 60 parts by weight, and S in a range of about 30 parts by weight to about 60 parts by weight.

In an embodiment, based on 100 parts by weight of the core, an amount of In and Ga may be in a range of about 20 parts by weight to about 50 parts by weight.

In an embodiment, based on 100 parts by weight of the core, an amount of Ga/(In+Ga) may be in a range of about 20 parts by weight to about 60 parts by weight, and within this range, the quantum dot may have a narrow full width of half maximum (FWHM).

In an embodiment, the first shell may include GaS, Ga₂S₃, GaSe, Ga₂Se₃, GaTe, InS, InSe, In₂S₃, In₂Se₃, InTe, or any combination thereof.

In an embodiment, the second shell may include a Group II-VI compound, a Group III-VI compound, or a combination thereof.

In an embodiment, the second shell may include ZnSe, ZnS, ZnTe, ZnO, ZnMg, ZnMgSe, ZnMgS, ZnMgAl, GaSe, GaTe, MgS, MgSe, or any combination thereof.

In an embodiment, a material included in the first shell may be identical to or different from a material included in the second shell.

In an embodiment, the first shell may include GaS, and the second shell may include ZnS.

In an embodiment, the quantum dot may further include an intermediate shell layer between the first shell layer and the second shell layer, wherein the intermediate shell layer may include a material identical to a material included in the first shell and a material included in the second shell.

In an embodiment, concentrations of the elements included in the first and second shell may form a concentration gradient (e.g., along a direction toward the core) according to a distance from the core.

In an embodiment, the quantum dot may further include a compound other than the aforementioned composition.

In an embodiment, a thickness of the first shell may be in a range of about 0.5 nm to about 3 nm, and for example may be 1 nm.

In an embodiment, a thickness of the second shell may be in a range of about 0.5 nm to about 4 nm, and for example, may be 2 nm.

The first and second shells of the quantum dot may each act as a protective layer to prevent or reduce chemical denaturation of the core and maintain semiconductor characteristics, and/or may each act as a charging layer to impart electrophoretic characteristics to the quantum dot.

In an embodiment, the first shell and/or the second shell may further include an oxide of metal and/or non-metal, a semiconductor compound, or a combination thereof.

In an embodiment, the quantum dot may emit green light having a maximum emission wavelength in a range of about 500 nm to about 590 nm. In an embodiment, the quantum dot may emit green light having a maximum emission wavelength in a range of about 500 nm to about 550 nm.

In an embodiment, an FWHM of a PL spectrum of the quantum dot may be about 80 nm or less, for example, about 70 nm or less. When the FWHM of the quantum dot is satisfied within the ranges above, the quantum dot may provide excellent color purity and color reproducibility.

In an embodiment, the quantum dot may have a quantum yield of 60% or more, for example, about 70% or more.

In an embodiment, the quantum yield of the quantum dot after purification with ethanol may be 70% or more, for example, 80% or more.

Next, a method of preparing the quantum dot according to an embodiment will be described in more detail.

The method of preparing the quantum dot according to an embodiment may include: preparing a core including copper (Cu), a Group III element, a Group VI element, and gallium (Ga);
preparing a first shell that covers the core; and
preparing a second shell that covers the first shell,
wherein the first shell may include a Group III-VI compound.

In an embodiment, in the preparing of the core, a composition for forming the core may be used to prepare the core, the composition including a Cu precursor, a precursor including a Group III element, a precursor including a Group VI element, and a Ga precursor.

In an embodiment, the precursor including a Group III element may be: aluminum and/or an aluminum-containing compound; gallium and/or a gallium-containing compound; indium and/or an indium-containing compound; and/or thallium and/or a thallium-containing compound.

For example, the precursor including a Group III element may be aluminum phosphate, aluminum acetylacetonate, aluminum chloride, aluminum fluoride, aluminum oxide, aluminum nitrate, aluminum sulfate, gallium acetylacetonate, gallium chloride, gallium fluoride, gallium oxide, gallium nitrate, gallium sulfate, indium acetate, indium chloride, indium oxide, indium nitrate, indium sulfate, indium carboxylate, and/or the like.

In an embodiment, the precursor including a Group VI element may be: sulfur and/or a sulfur-containing compound; selenium and/or a selenium-containing compound; and/or tellurium and/or a tellurium-containing compound.

For example, the precursor including a Group VI element may be sulfur, trialkylphosphine sulfide, trialkenylphosphine sulfide, alkylamino sulfide, alkenylamino sulfide, alkylthiol, selenium, trialkylphosphine selenide, trialkenylphosphine selenide, alkylamino selenide, alkenylamino selenide, trialkylphosphine telluride, trialkenylphosphine telluride, alkylamino telluride, alkenylamino telluride, and/or the like.

In an embodiment, the composition for forming the quantum dot may further include a solvent.

In an embodiment, the solvent may be an organic solvent. For example, the solvent may include 1-octadecene (ODE), trioctylamine (TOA), trioctylphosphine (TOP), or any combination thereof.

In an embodiment, in the preparing of the core, the composition for forming the core may undergo a cation exchange reaction at a temperature in a range of about 210° C. to about 340° C.

In the method of preparing the quantum dot according to an embodiment, the composition for forming the core may undergo the cation exchange reaction at a temperature in a range of about 210° C. to about 340° C., so that the core may have a suitable or appropriate composition ratio, and accordingly, the core may be evenly synthesized to evenly form the shell on the core, thereby improving chemical stability and photoluminescence (PL) characteristics.

In an embodiment, in the preparing of the second shell, a composition for forming the second shell may be used to form the second shell, the composition including two or more of a precursor including a Group II element, a precursor including a Group III element, and/or a precursor including a Group VI element.

In an embodiment, the composition for forming the second shell may include the precursor including the Group II element and the precursor including the Group VI element.

In an embodiment, the precursor including a Group II element may be: zinc and/or a zinc-containing compound; cadmium and/or a cadmium-containing compound; and/or mercury and/or a mercury-containing compound.

For example, the precursor including a Group II element may be zinc acetate, dimethyl zinc, diethyl zinc, zinc carboxylate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, cadmium oxide, dimethyl cadmium, diethyl cadmium, cadmium carbonate, cadmium acetate dihydrate, cadmium acetylacetonate, cadmium fluoride, cadmium chloride, cadmium iodide, cadmium bromide, cadmium perchlorate, cadmium phosphide, cadmium nitrate, cadmium sulfate, cadmium carboxylate, mercury iodide, mercury bromide, mercury fluoride, mercury cyanide, mercury nitrate, mercury perchlorate, mercury sulfate, mercury oxide, mercury carbonate, mercury carboxylate, and/or the like.

In an embodiment, the precursor including a Group II element may be zinc acetate, and the precursor including a Group VI element may be trioctylphosphine sulfide.

In an embodiment, the composition for forming the second shell may further include a solvent.

In an embodiment, the solvent may be oleylamine.

By the method of preparing the quantum dot according to an embodiment, zinc acetate, trioctylposphine sulfide, and oleylamine may be used to synthesize the second shell so that, through this combination, a ZnS shell having high stability may be synthesized. In addition, a GaS shell may be formed as a buffer layer between the core and the second shell, thereby improving chemical stability and PL characteristics.

In an embodiment, the method of preparing the quantum dot may further include surface-treating the second shell with an organic ligand and/or a metal halide.

In an embodiment, the organic ligand may include a C₄-C₃₀ fatty acid.

For example, the organic ligand may include palmitic acid, palmitoleic acid, stearic acid, oleic acid, trioctylphosphine, trioctylphosphine oxide, oleylamine, octylamine, trioctyl amine, hexadecylamine, octanethiol, dodecanethiol, hexylphosphonic acid, tetradecylphosphonic acid, octylphosphonic acid, and/or the like.

### Electronic Apparatus

Quantum dots may be included in various suitable electronic apparatuses. For example, an electronic apparatus including the quantum dots may be a light-emitting apparatus, an authentication apparatus, and/or the like.

The electronic apparatus (for example, a light-emitting apparatus and/or a display apparatus) may further include, in addition to a light-emitting device, i) a color filter, ii) a color conversion layer, or iii) a color filter and a color conversion layer. The color filter and/or the color conversion layer may be arranged in at least one traveling direction of light emitted from the light-emitting device. For example, the light emitted from the light-emitting device may be blue light or white light. In an embodiment, the light-emitting device may include the quantum dots. In an embodiment, the color conversion layer may include a quantum dot. The quantum dot may be, for example, the quantum dot as described herein.

The electronic apparatus may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, various measuring instruments, meters (for example, meters for a vehicle, an aircraft, and/or a vessel), projectors, and/or the like.

Hereinafter, methods of preparing quantum dots according to examples will be described in more detail.

### Example 1: Preparation of CIGS/GaS/ZnS Quantum Dots

### Synthesis of CuInGaS Core

CuI in an amount of 0.1 mmol to 1 mmol, Ga(acac)₃ in an amount of 0.3 mmol to 1 mmol, InCl₃ in an amount of 0.1 mmol to 0.5 mmol, oleylamine in an amount of 10 mmol to 50 mmol, trioctylphosphine oxide (TOPO) in an amount of 0.1 mmol to 1 mmol, and trioctylamine (TOA) in an amount of 1 mmol to 20 mmol were added together to a three-neck flask, and mixed together. By degassing and stirring the mixture at 120° C. for 60 minutes, oxygen and moisture inside the flask were removed, so as to prepare a reaction solution. Afterwards, in an argon atmosphere, sulfur-oleylamine in an amount of 1 mmol to 2 mmol was added to the reaction solution, and the reaction temperature was raised to 240° C. After maintaining for a certain time and then cooling to 200° C., 4.48 mmol of trioctylphosphine (TOP) was added thereto and reacted for a certain time, so as to synthesize a core.

### Synthesis of First Shell (GaS Shell)

The synthesized CuInGaS core was diluted in toluene and purified by precipitation with ethanol. To oleylamine undergoing degassing at 120° C., the CuInGaS core in an amount of 1 mmol to 2 mmol, S-oleylamine in an amount of 0.8 mmol, and GaCl₃ in an amount of 1.14 mmol were added, so as to form a GaS shell at 200° ° C. or higher.

### Synthesis of Second Shell (ZnS Shell)

The synthesized CuInGaS/GaS quantum dots were diluted in toluene and purified by precipitation with ethanol. Next, the purified CuInGaS/GaS quantum dots in an amount of 0.1 mmol to 100 mmol were dispersed in toluene, and mixed together with oleylamine in an amount of 10 mmol to 100 mmol, followed by degassing at 120° C. Afterwards, 1.6 mmol of zinc acetate and 2.27 mmol of trioctylphosphine sulfide were added thereto, so as to form a ZnS shell at 200° C. or higher.

### Comparative Example 1

### Synthesis of CuInGaS Core

CuI in an amount of 1.1 mmol to 1.5 mmol, Ga(acac)₃ in an amount of 0.3 mmol to 1 mmol, InCl₃ in an amount of 0.1 mmol to 0.5 mmol, oleylamine in an amount of 10 mmol to 50 mmol, trioctylphosphine oxide (TOPO) in an amount of 0.1 mmol to 1 mmol, and trioctylamine (TOA) in an amount of 1 mmol to 20 mmol were added together to a three-neck flask, and mixed together. By degassing and stirring the mixture at 120° C. for 60 minutes, oxygen and moisture inside the flask were removed, so as to prepare a reaction solution. Afterwards, in an argon atmosphere, sulfur-oleylamine in an amount of 1 mmol to 2 mmol was added to the reaction solution, and the reaction temperature was raised to 260° C. After maintaining for a certain time and then cooling to 200° C., 4.48 mmol of trioctylphosphine (TOP) was added thereto and reacted for a certain time, so as to synthesize a core.

Synthesis of GaS shell

The synthesized CuInGaS core was diluted in toluene and purified by precipitation with ethanol. To oleylamine undergoing degassing at 120° C., the CuInGaS core in an amount of 1 mmol to 2 mmol, S-oleylamine in an amount of 0.4 mmol, and GaCl₃ in an amount of 0.57 mmol were added, so as to form a GaS shell at 200° ° C. or higher.

### Comparative Example 2

### Synthesis of CIGS Core

CuI in an amount of 1.1 mmol to 1.5 mmol, Ga(acac)₃ in an amount of 0.3 mmol to 1 mmol, InCl₃ in an amount of 0.1 mmol to 0.5 mmol, oleylamine in an amount of 10 mmol to 50 mmol, TOPO in an amount of 0.1 mmol to 1 mmol, and TOA in an amount of 1 mmol to 20 mmol were added together to a three-neck flask, and mixed together. By degassing and stirring the mixture at 120° C. for 60 minutes, oxygen and moisture inside the flask were removed, so as to prepare a reaction solution. Afterwards, in an argon atmosphere, sulfur-oleylamine in an amount of 1 mmol to 2 mmol was added to the reaction solution, and the reaction temperature was raised to 260° C. After maintaining for a certain time and then cooling to 200° C., 4.48 mmol of TOP was added thereto and reacted for a certain time, so as to synthesize a core.

### Synthesis of ZnS Shell

The synthesized CuInGaS/GaS quantum dots were diluted in toluene and purified by precipitation with ethanol. Next, the purified CuInGaS/GaS quantum dots in an amount of 0.1 mmol to 10 mmol were dispersed in toluene, and mixed together with oleylamine in an amount of 10 mmol to 100 mmol, followed by degassing at 120° C. Afterwards, 3.2 mmol of zinc acetate and 4.5 mmol of trioctylphosphine sulfide were added thereto, so as to form a ZnS shell at 200° C. or higher.

### Comparative Example 3

### Synthesis of CuInGaS Core

CuI in an amount of 1.1 mmol to 1.5 mmol, Ga(acac)₃ in an amount of 0.3 mmol to 1 mmol, InCl₃ in an amount of 0.1 mmol to 0.5 mmol, oleylamine in an amount of 10 mmol to 50 mmol, TOPO in an amount of 0.1 mmol to 1 mmol, and TOA in an amount of 1 mmol to 20 mmol were added together to a three-neck flask, and mixed together. By degassing and stirring the mixture at 120° C. for 60 minutes, oxygen and moisture inside the flask were removed, so as to prepare a reaction solution. Afterwards, in an argon atmosphere, sulfur-oleylamine in an amount of 1 mmol to 2 mmol was added to the reaction solution, and the reaction temperature was raised to 260° C. After maintaining for a certain time and then cooling to 200° C., 4.48 mmol of TOP was added thereto and reacted for a certain time, so as to synthesize a core.

### Synthesis of First Shell (GaS Shell)

The synthesized CuInGaS core was diluted in toluene and purified by precipitation with ethanol. To oleylamine undergoing degassing at 120° C., the CuInGaS core in an amount of 1 mmol to 2 mmol, S-oleylamine in an amount of 0.4 mmol, and GaCl₃ in an amount of 0.57 mmol were added, so as to form a GaS shell at 200° C. or higher.

### Synthesis of Second Shell (ZnS Shell)

The synthesized CuInGaS/GaS quantum dots were diluted in toluene and purified by precipitation with ethanol. Next, the purified CuInGaS/GaS quantum dots in an amount of 0.1 mmol to 10 mmol were dispersed in toluene, and mixed together with oleylamine in an amount of 10 mmol to 100 mmol, followed by degassing at 120° C. Afterwards, 3.2 mmol of zinc acetate and 4.5 mmol of trioctylphosphine sulfide were added thereto, so as to form a ZnS shell at 200° C. or higher.

### Evaluation Example: Evaluation of Quantum Dot Characteristics

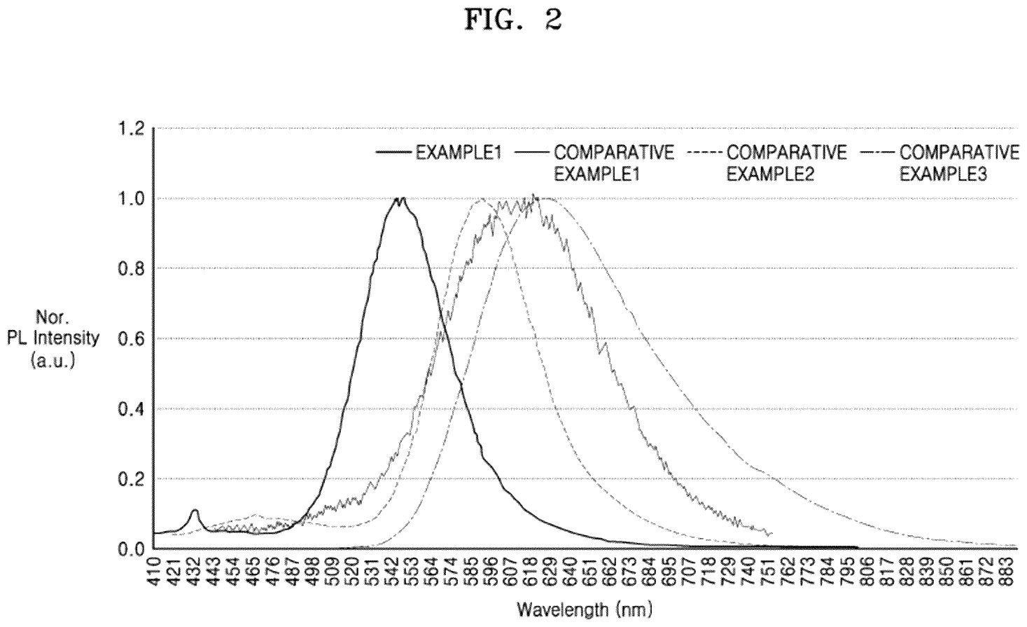

For each of the quantum dots of Example 1 and Comparative Examples 1 to 3, maximum emission wavelength, FWHM, quantum yield (QY), and QY retention rate were evaluated, and the results are shown in Table 1. Also, PL spectra for the quantum dots at 25° C. are shown in FIG. 2.

The measurement method was as follows: after 2.8 ml of toluene and 0.2 ml of the quantum dots were dispersed in a quartz cuvette, and the maximum emission wavelength and FWHM were evaluated by analyzing the PL spectrum measured using a PL spectrometer and a UV-vis spectrometer. The QY was evaluated using an absolute quantum efficiency measuring equipment, and the QY retention rate was calculated as follows: QY after purifying quantum dots with ethanol three times/QY of unpurified quantum dots.

TABLE 1

| | Ga in | | | | | | |
|---|---|---|---|---|---|---|---|
| | core/(In + Ga) | | Maximum | | | | QY |
| | atom | | emission | | | | retention |
| | percentage | | wavelength | FWHM | | QY | rate |
| | (%) | Shell | (nm) | (nm) | | (%) | (%) |
| Example 1 | 41% | GaS/ZnS | 542 nm | 65 | nm | 71% | 86% |
| Comparative | 18% | ZnS | 605 nm | 103 | nm | 73% | 84% |
| Example 1 | | | | | | | |
| Comparative | 72% | GaS | 591 nm | 76 | nm | 16% | 58% |
| Example 2 | | | | | | | |
| Comparative | 15% | GaS/ZnS | 627 nm | 111 | nm | 68% | 62% |
| Example 3 | | | | | | | |

Referring to FIG. 2, it can be seen that the quantum dot according to Example 1 had excellent PL characteristics compared to the quantum dots according to Comparative Examples 1 to 3.

Referring to Table 1, it can be seen that the quantum dots prepared according to the method of preparing the quantum dot according to an embodiment also had a narrow FWHM, a high QY, and a high QY retention rate.

According to one or more embodiments, a quantum dot prepared according to a method of preparing the quantum dot may have a narrow FWHM by improving or optimizing a substitution composition of Cu, In, and Ga, and thus a core may be evenly synthesized and a shell may be also evenly formed on the core. In addition, by forming a double-shell structure consisting of GaS and ZnS, the chemical stability and PL characteristics may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and equivalents thereof.

What is claimed is:

1. A quantum dot comprising:
a core comprising copper (Cu), a Group III element, a Group VI element, and gallium (Ga);
a first shell covering the core; and
a second shell covering the first shell,
wherein the first shell comprises a Group III-VI compound.

2. The quantum dot of claim 1, wherein an amount of Ga included in the core is in a range of about 20 parts by weight to about 60 parts by weight based on 100 parts by weight of the Group III element.

3. The quantum dot of claim 1, wherein the core comprises Cu, indium (In), Ga, and sulfur (S).

4. The quantum dot of claim 3, wherein the core comprises, based on 100 parts by weight of the core, an amount of Cu in a range of about 5 parts by weight to about 20 parts by weight, an amount of In in a range of about 10 parts by weight to about 30 parts by weight, an amount of Ga in a range of about 10 parts by weight to about 60 parts by weight, and an amount of S in a range of about 30 parts by weight to about 60 parts by weight.

5. The quantum dot of claim 1, wherein the first shell comprises GaS, Ga₂S₃, GaSe, Ga₂Se₃, GaTe, InS, InSe, In₂S₃, In₂Se₃, InTe, or any combination thereof.

6. The quantum dot of claim 1, wherein the second shell comprises a Group II-VI compound, a Group III-VI compound, or any combination thereof.

7. The quantum dot of claim 1, wherein the second shell comprises ZnSe, ZnS, ZnTe, ZnO, ZnMg, ZnMgSe, ZnMgS, ZnMgAl, GaSe, GaTe, MgS, MgSe, or any combination thereof.

8. The quantum dot of claim 1, further comprising an intermediate shell between the first shell and the second shell,
wherein the intermediate shell layer comprises a material identical to materials included in the first and second shells.

9. The quantum dot of claim 1, wherein concentrations of the elements included in the first and second shell form a concentration gradient according to a distance from the core.

10. The quantum dot of claim 1, wherein a thickness of the first shell is in a range of about 0.5 nm to about 3 nm.

11. The quantum dot of claim 1, wherein a thickness of the second shell is in a range of about 0.5 nm to about 4 nm.

12. The quantum dot of claim 1, wherein the quantum dot emits green light having a maximum emission wavelength in a range of about 500 nm to about 550 nm.

13. The quantum dot of claim 1, wherein a full width of half maximum (FWHM) of a photoluminescence spectrum of the quantum dot is 70 nm or less.

14. A method of preparing a quantum dot, the method comprising:
preparing a core comprising copper (Cu), a Group III element, a Group VI element, and gallium (Ga);
preparing a first shell covering the core; and
preparing a second shell covering the first shell,
wherein the first shell comprises a Group III-VI compound.

15. The method of claim 14, wherein, in the preparing of the core, a composition for forming the core is used to form the core, the composition for forming the core comprising a Cu precursor, a precursor comprising a Group III element, a precursor comprising a Group VI element, and a Ga precursor.

16. The method of claim 15, wherein, in the preparing of the core, the composition for forming the core undergoes a cation exchange reaction at a temperature in a range of 210° C. to about 340° C.

17. The method of claim 14, wherein, in the preparing of the second shell, a composition for forming the second shell is used to form the second shell, the composition for forming the second shell comprising at least two of a precursor comprising a Group II element, a precursor comprising a Group III element, and a precursor comprising a Group VI element.

18. The method of claim 17, wherein
the composition for forming the second shell comprises the precursor comprising a Group II element and the precursor comprising a Group VI element,
the precursor comprising a Group II element is zinc acetate,
the precursor comprising a Group VI element is trioctylphosphine sulfide,
the composition for forming the second shell further comprises a solvent, and
the solvent is oleylamine.

19. The method of claim 14, further comprising treating a surface of the second shell with an organic ligand and/or a metal halide.

20. An electronic apparatus comprising the quantum dot of claim 1.
